(19) United States
(12) Patent Application Publication
(10) Pub. No.: US 2015/0228698 A1
(43) Pub. Date: Aug. 13, 2015

(54) PORTABLE INFORMATION APPLIANCE

(71) Applicant: Konica Minolta Inc., Tokyo (JP)

(72) Inventors: Yusuke Kawahara, Koganei-shi (JP); Nobuya Miki, Ibaraki-shi (JP)

(21) Appl. No.: 14/420,263

(22) PCT Filed: Jul. 31, 2013
(86) PCT No.: PCT/JP2013/070688

§ 371 Date: Feb. 6, 2015

(30) Foreign Application Priority Data
Aug. 20, 2012 (JP) 2012-181276

(51) Int. Cl. H01L 27/32; H01L 51/52

(52) U.S. Cl. CPC H01L 27/3239; H01L 51/5262

(57) ABSTRACT

An object of the present invention is to provide a portable information appliance having a thin organic electroluminescent illumination panel capable of color adjustment and uniform light emission.

The portable information appliance according to the present invention is a portable information appliance having a thin organic electroluminescent illumination panel wherein the organic electroluminescent illumination panel is integrated with a front transmissive member and fitted into an exterior member of the portable information appliance.

### TECHNICAL FIELD

The present invention relates to a portable information appliance, and more specifically to a portable information appliance having a thin organic electroluminescent illumination panel capable of color adjustment and uniform light emission.

### BACKGROUND ART

In recent years, the information appliances that can be carried (hereinafter referred to as “portable information appliance”) have been widely used. Technical innovations of the portable information appliances, such as the reduction of the thickness, size, and weight, have been advanced so that the appliances do not interrupt even when being carried in a breast pocket or a bag while the high functionality is realized to meet the demand of the market for achieving the portability and wearability and improve the convenience.

As an example of the high functionality, a portable information appliance where a logo on the rear surface side is illuminated or auxiliary light such as flash light is provided on the rear surface side has been desired.

There have been examples of the portable information appliance with the logo illuminated or a cellular phone or a digital camera having an LED (Light Emitting Diode) or the like emitting the auxiliary light (for example, see Patent Literatures 1 to 3). In these examples, since the board is large, it has been difficult to reduce the thickness or size thereof and to apply those to the portable information appliance whose size reduction is particularly required. Moreover, the light emission has been inhomogeneous and insufficient, which causes a problem in visibility. In addition, the heat generation by the driving of the LED may cause the deformation of the case. Further, the conventional example of using the LED realizes just the monochromatic light emission, and for the logo illumination, the user's desire has not been sufficiently satisfied. Although Patent Literature 4 discloses the use of electroluminescence as the auxiliary light, the literature merely describes the technique related to the focusing of the auxiliary light and does not disclose the above subject related to the electroluminescence.

### CITATION LIST

### Patent Literatures

### Patent Literature 1: JP 2002-56992 A

### Patent Literature 2: JP 2005-346027 A

### Patent Literature 3: JP 2010-055073 A

### Patent Literature 4: US 2011/0032712 A

### SUMMARY OF INVENTION

### Technical Problem

The present invention has been made in view of the above problem and circumstances, and a solution therefor is to provide a portable information appliance with a thin organic electroluminescent illumination panel capable of color adjustment and uniform light emission.

### Solution to Problem

As a result of studies of the cause of the problem for solving the problem, the present inventor has found out that an organic electroluminescent illumination panel integrated with a front transmissive member and fitted into an exterior member of the portable information appliance is particularly effective for the thickness reduction.

In other words, the problem is solved by a solution as below.

1. A portable information appliance comprising an organic electroluminescent illumination panel, wherein the organic electroluminescent illumination panel is integrated with a front transmissive member and fitted into an exterior member of the portable information appliance.

2. The portable information appliance according to Item. 1, wherein the organic electroluminescent illumination panel is capable of color adjustment.

3. The portable information appliance according to Item. 1 or 2, wherein the organic electroluminescent illumination panel is used as auxiliary light in photographing.

4. The portable information appliance according to any one of Items. 1 to 3, wherein the organic electroluminescent illumination panel is used to illuminate a logo mark.

5. The portable information appliance according to any one of Items. 1 to 4, wherein the organic electroluminescent illumination panel is used for illumination that notifies an incoming call.

6. The portable information appliance according to any one of Items. 1 to 5, wherein the portable information appliance is any of a tablet type terminal, a smart phone, and a digital camera.

### Advantageous Effects of Invention

According to the above solution of the present invention, a portable information appliance with a thin organic electroluminescent illumination panel capable of color adjustment and uniform light emission can be provided.

In the present application, a thin organic electroluminescent element is used as an organic electroluminescent illumination panel and the organic electroluminescent illumination panel and a front transmissive member are integrated; thus, the assembly with the exterior is facilitated and by incorporating the panel into a portable terminal, the size increase of the portable information appliance can be prevented and the uniform illumination becomes possible. The above problem can be solved in this manner.

### BRIEF DESCRIPTION OF DRAWINGS

FIG. 1 illustrates an example of a sectional diagram of a portable information appliance according to the present invention.

FIG. 2A illustrates an example of the application to a smart phone (front surface).

FIG. 2B illustrates an example of the application to the smart phone (rear surface).

FIG. 3A illustrates an example of the application to a tablet terminal (front surface).

FIG. 3B illustrates an example of the application to the tablet terminal (rear surface).

FIG. 4 illustrates an example of a structure of an organic electroluminescent illumination panel.

FIG. 5 illustrates an example of a structure of a tandem type organic electroluminescent illumination panel.

### DESCRIPTION OF EMBODIMENTS

A portable information appliance of the present invention is a portable information appliance having an organic electroluminescent illumination panel, wherein the organic electroluminescent illumination panel is integrated with a front transmissive member and is fitted into an exterior member of the portable information appliance. This feature is a technical feature common among the inventions according to claims 1 to 5.

In an aspect of the present invention, the organic electroluminescent illumination panel is preferably capable of color adjustment. Moreover, the organic electroluminescent illumination panel is preferably used as auxiliary light in the photographing.

Moreover, in the present invention, the organic electroluminescent illumination panel is preferably used in the illumination of a logo mark or the illumination that notifies the incoming call.

It is preferable that the portable information appliance is any of a tablet type information terminal, a smart phone, and a digital camera because the thinness is required particularly.

Detailed description is hereinafter made of the present invention, the component of the present invention, and embodiments and modes for carrying out the present invention. In the present application, the numerals before and after “-” are included as the lower limit and the upper limit.

<Portable Information Appliance>

In the present invention, the portable information appliance refers to an information appliance for an individual, which is small enough to be carried. For example, a tablet type information terminal such as iPad (registered trademark), a smart phone with an information communication function, such as iPhone (registered trademark), a portable personal computer, a digital camera, a game machine, PHS, and the like are included.

Among these, it is particularly preferable that the portable information appliance according to the present invention is a tablet type terminal, a smart phone, or a digital camera because the thinness is required.

<Summary of Portable Information Appliance with Organic Electroluminescent Illumination Panel>

A portable information appliance according to the present invention is a portable information appliance with an organic electroluminescent illumination panel, wherein the organic electroluminescent illumination panel is integrated with a front transmissive member and fitted into an exterior member of the portable information appliance.

Conventionally, for illuminating the logo, for example, the exterior member is provided with a transparent window through which an LED illuminates the logo from the rear surface. In particular, in the portable information appliance, such a transparent window has been used to protect the inside from water or dust.

For uniformly illuminating a display portion without luminance unevenness, however, a devise has been necessary; for example, a diffusion surface and an LED are separated or a light guide plate is provided, because the LED is a point light source. As a result, the reduction in thickness has been difficult. The organic electroluminescent illumination panel has a thin light-emitting portion and is a plane light source, so that this panel is suitable for uniform illumination or reduction of thickness of the appliance. However, just using the organic electroluminescent illumination panel instead of the LED still leaves the problems that the reflow onto the substrate is impossible because the organic electroluminescent illumination panel includes an organic material, the mount area becomes relatively larger to increase the size of the substrate because the organic electroluminescent illumination panel is a plane light source, and the like. In view of this, in the present invention, the organic electroluminescent illumination panel and the front transmissive member are integrated to be treated as one component and taken into the exterior substrate, whereby the above problems are solved.

Description is hereinafter made of the summary of the portable information appliance with the organic electroluminescent illumination panel with reference to drawings.

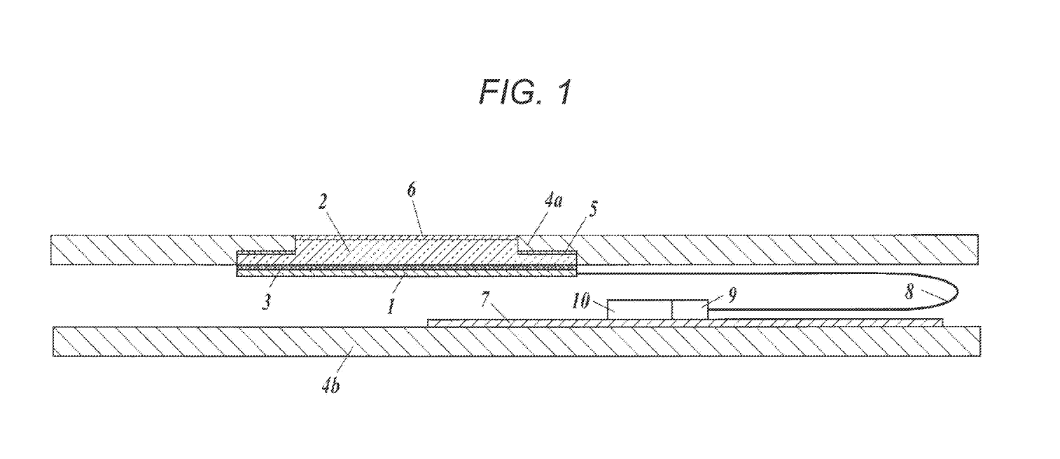

FIG. 1 illustrates an example of a sectional diagram of a portable information appliance according to the present invention. An organic electroluminescent illumination panel 1 including an organic electroluminescent element, and a front transmissive member 2 are integrated through a transparent adhesive 3, and fitted into an exterior member 4a with the use of a double-sided tape 5. A surface of the front transmissive member 2, which is opposite to a surface thereof provided with the organic electroluminescent illumination panel 1, is provided with a diffusion plate 6. A circuit board 7 is provided on an exterior member 4b on the opposite side (rear surface) of the exterior member 4a provided with the organic electroluminescent illumination panel 1. This circuit board 7 is connected to the organic electroluminescent illumination panel 1 through a flexible wire 8, an organic electroluminescent illumination panel connector 9, and a circuit board side connector 10.

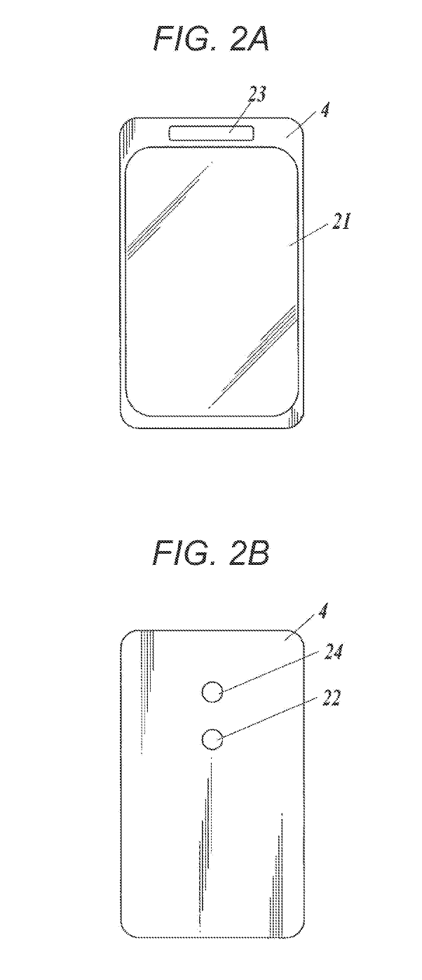

FIG. 2 is a schematic diagram illustrating an example of the application to a smart phone. FIG. 2A illustrates a surface of a smart phone. In addition to a display screen 21 where various pieces of image information and text information are displayed, a light-emitting portion 23 where a logo mark or a product name can be illuminated by the organic electroluminescent illumination panel 1 is provided. The light-emitting portion 23 can be used as the illumination that notifies the incoming call or text. FIG. 2B illustrates a rear surface of the smart phone. An upper part of a photographing lens 22 can be provided with a light-emitting portion 24 where the light can be emitted by the organic electroluminescent illumination as the auxiliary light such as flash light. The light-emitting portion corresponds to a light-emitting portion seen from the outside of the exterior member of the organic electroluminescent illumination panel integrated with the front transmissive member and fitted into the exterior member 4.

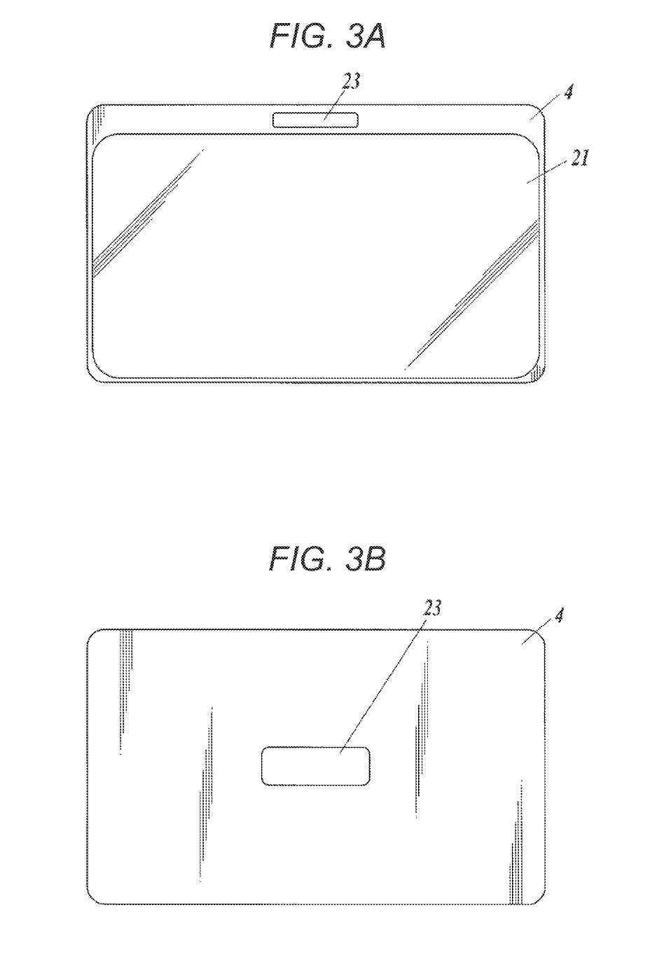

FIG. 3 illustrates an example of the application to a tablet terminal. FIG. 3A illustrates a surface of a tablet terminal. In addition to the display screen 21, the light-emitting portion 23 where a logo mark or a product name can be illuminated by the organic electroluminescent illumination panel 1 is provided. FIG. 3B illustrates a rear surface of the tablet terminal. The light-emitting portion 23 where a logo mark or a product name can be illuminated by the organic electroluminescent illumination panel 1 is provided.

Detailed description is hereinafter made.

<Organic Electroluminescent Illumination Panel Integrated with Front Transmissive Member>

In the present invention, the organic electroluminescent illumination panel is integrated with the front transmissive member. The integrated structure includes at least the organic electroluminescent illumination panel 1 including the organic electroluminescent element, the front transmissive member 2, the transparent adhesive 3, the flexible wire 8, and the organic electroluminescent illumination panel connector 9. The double-sided tape 5, the diffusion plate 6, and the like may be provided as necessary.

The front transmissive member 2 is formed of a resin member with a light-transmitting property, such as polycarbonate resin or acrylic resin, and is fixed to an exterior cover. A method of fixing may be, for example, a double-sided tape.

In general, in the organic electroluminescent illumination panel, the extraction efficiency, i.e., the emission efficiency is improved by providing a panel surface with a sheet that enables the extraction, such as a PET sheet with the diffusing property. As described above, the organic electroluminescent illumination panel and the front transmissive member are optically integrated by the attachment; therefore, providing the surface of the front transmissive member with the diffusing property improves the emission efficiency.

As an alternative to the attachment of the diffusion plate 6 as illustrated in FIG. 1, unevenness with the embossed shape may be provided on the surface of the front transmissive member to provide the diffusing property. In the latter case, the unevenness may be provided in the die in the molding of the resin, so that the emission efficiency can be improved without increasing the number of components. The position of the light extraction portion may be on the surface of the organic electroluminescent illumination panel instead of on the surface of the front transmissive member.

As the transparent adhesive 3 used in the adhesion between the organic electroluminescent illumination panel 1 and the front transmissive member 2 including polycarbonate resin or acrylic resin, the adhesive with a light-transmitting property is used. As the material, acrylic-based, silicon-based, polyether-based adhesive or the like is given; any material can be used as long as the close adhesion is possible without leaving an air layer between the front transmissive member and the panel. The adhesive has a refractive index of approximately 1.5, which is larger than that of the air, and after the attachment, the emission light from the organic electroluminescent illumination panel enters the transparent member without being totally reflected on the panel surface. Therefore, optically, this is substantially equal to the increase of the thickness of the organic electroluminescent illumination panel.

In the case of illuminating a graphic or letter, a graphic pattern or a letter pattern is printed on the rear surface side of the front transmissive member (on the organic electroluminescent illumination panel side) and an unnecessary portion is shielded, whereby just the pattern can be illuminated. If the pattern is not complicated, the exterior member is cut along each pattern and this is combined with the organic electroluminescent illumination panel to illuminate the pattern. If the pattern is white, the diffusion surface can be formed by half-transmissive printing. Moreover, by overlapping the color filter on the pattern, not just the entire color but also the color of a part of the pattern can be changed.

The flexible wire 8 for current supply or a control signal is led out from the organic electroluminescent illumination panel, and by connecting a connector at the end of the flexible wire 8 and a connector on the circuit board, the current supply or the emission of the organic electroluminescent illumination panel is controlled. Alternatively, a connector pin may be provided and the contact may be established after fastening the exterior cover.

<Organic Electroluminescent Illumination Panel>

An organic electroluminescent illumination panel according to the present invention includes an organic electroluminescent element, and the organic electroluminescent illumination panel and a front transmissive member are integrated and fitted into an exterior member of the portable information appliance. The organic electroluminescent illumination panel is preferably capable of color adjustment. Moreover, the organic electroluminescent illumination panel is preferably used as the auxiliary light in the photographing. In addition, the organic electroluminescent illumination panel is preferably used in the illumination of the logo mark. Furthermore, the organic electroluminescent illumination panel is preferably used in the illumination that notifies the incoming call.

<Light-Emitting Portion>

The light-emitting portion as the surface portion of the organic electroluminescent illumination integrated with the front transmissive member and fitted into the exterior member 4 may be more than one in the exterior member. If there is a plurality of organic electroluminescent illumination panels, the illumination of the logo mark, the illumination for the incoming call, and the auxiliary light in the photographing can be realized. Alternatively, one organic electroluminescent illumination panel can achieve the illumination of the logo mark, the illumination for the incoming call, and the emission of the auxiliary light. In this case, the circuit board can control the amount of light and emission color.

In the case of the illumination of the logo mark or the illumination for the incoming call, the emission luminance is preferably 50 to 800 cd/m²; in the case of the flash emission as the auxiliary light, the luminance is preferably 5000 to 80000 cd/m².

In the case of the illumination of the logo mark or the illumination for the incoming call, the luminous flux is preferably 0.024 to 0.380 lm; in the case of the flash emission as the auxiliary light, the luminance is preferably 2.5 to 40 lm.

In the case of the flash emission, the flash light is preferably white light including blue, green, and red light from the viewpoint of color rendering.

The size of the light-emitting portion is preferably within 50%, more preferably 2 to 30%, of the area of the front surface or the rear surface. Since the heat generation is small enough to prevent the distortion in the case of the organic electroluminescent illumination panel, the light-emitting portion may be positioned locally or occupy a small area.

<Color Adjustment>

Being capable of color adjustment in the present invention refers to the fact that emission is possible in any color when the organic electroluminescent illumination panel emits light, and any kind of color including three primary colors and other intermediate colors is applicable. The organic electroluminescent illumination panel that satisfies the above condition is preferably the organic electroluminescent illumination panel with the white-light-emitting property having a light-emitting layer containing a blue-light-emitting compound, a green-light-emitting compound, and a red-light-emitting compound as the light-emitting compound.

A specific method to enable the color adjustment of the organic electroluminescent illumination panel is public, and any of the known methods may be used.

For example, the following methods can be used:

(1) A method in which the organic electroluminescent illumination panel has pixels with different emission colors arranged two-dimensionally in a plane direction, and the emission color of the panel is adjusted by controlling the emission condition of the pixels.
(2) A method in which two or more light-emitting layers with different emission colors are stacked and the emission color is controlled by moving the emission center while controlling the current or voltage drive.
(3) A method in which two or more light-emitting layers with different emission colors are stacked and an electrochromic element, a photochromic element, and a thermochromic element are provided between the light-emitting layers, and the emission color is controlled by adjusting the layers.
(4) A method in which a plurality of light-emitting units each having two or more light-emitting layers with different emission colors is stacked with an intermediate electrode provided between the light-emitting units, and the emission color is controlled by driving each light-emitting unit.
(5) A method in which two or more organic electroluminescent illumination panels with high light-transmitting property are stacked and the emission color is controlled by adjusting the emission driving for each panel. These methods may be used alone or in combination.

<Structure of Organic Electroluminescent Illumination Panel>

The main structure of the organic electroluminescent illumination panel includes a pair of surface electrodes (anode, cathode) on a support substrate, and an organic function layer including an organic light-emitting layer between the surface electrodes. As the organic function layer, generally, a hole injection layer, a hole transport layer, a light-emitting layer, an electron transport layer, an electron injection layer, and the like are given from the anode side. These layers may be combined into a composite layer in accordance with the characteristic of the materials to be used, thereby reducing the number of layers, or alternatively, another function layer may be added. In regard to the structure of the organic electroluminescent illumination panel, for example, “Organic EL handbook” (supervisor: Tetsuo Tsutsui; published by REALIZE Science & Engineering) may be referred to.

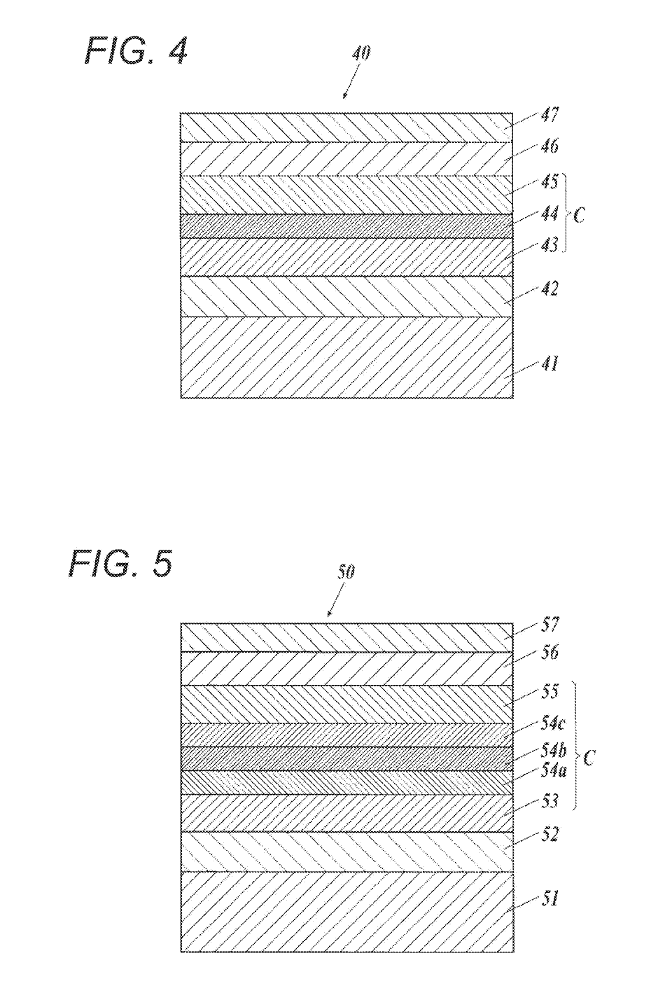

FIG. 4 is a schematic sectional diagram illustrating an example of the structure of the organic electroluminescent illumination panel according to the present invention.

In FIG. 4, an organic electroluminescent illumination panel 40 includes a transparent electrode 42 formed of indium-tin composite oxide (hereinafter abbreviated as ITO) as an anode on a support substrate 41 formed of plastic film with a light-transmitting property or glass, and an organic function layer unit C is formed thereon. The organic function layer unit C is formed by, in addition to an organic light-emitting layer 44, organic function layers 43 and 45 such as a hole transport layer, a hole block layer, and an electron transport layer. On the organic function layer unit C, for example, an electrode 46 made of aluminum is provided as a cathode, and a sealing member (sealing layer) 47 is provided as the outermost layer.

FIG. 5 is a schematic sectional diagram illustrating an example of a structure of a tandem type organic electroluminescent illumination panel in which a plurality of light-emitting layers is stacked. An organic electroluminescent illumination panel 50 illustrated in FIG. 5 has a stack of light-emitting layers. The light-emitting layer is different from the light-emitting layer 44 in FIG. 4 in that the light-emitting layer includes three layers of a blue-light-emitting layer 54a containing a blue-light-emitting compound, a green-light-emitting layer 54b containing a green-light-emitting compound, and a red-light-emitting layer 54c containing a red-light-emitting compound. An intermediate layer may be provided between the light-emitting layers. The provision of the intermediate electrode between the light-emitting layers is preferable because the color adjustment becomes easier.

Note that the layer structures of the organic electroluminescent illumination panel illustrated in FIG. 4 and FIG. 5 are just the preferable specific examples, and the present invention is not limited thereto. For example, as the structure of the organic electroluminescent illumination panel according to the present invention, the layer structures (i) to (v) below may be employed. The light-emitting layer preferably includes the blue-light-emitting layer, the green-light-emitting layer, and the red-light-emitting layer as described with reference to FIG. 5.

(i) Support substrate/anode/light-emitting layer/electron transport layer/cathode/sealing adhesive/sealing member
(ii) Support substrate/anode/hole transport layer/light-emitting layer/electron transport layer/cathode/sealing adhesive/sealing member
(iii) Support substrate/anode/hole transport layer/light-emitting layer/hole block layer/electron transport layer/cathode/sealing adhesive/sealing member
(iv) Support substrate/anode/hole transport layer/light-emitting layer/hole block layer/electron transport layer/cathode buffer layer/cathode/sealing adhesive/sealing member
(v) Support substrate/anode/anode buffer layer/hole transport layer/light-emitting layer/hole block layer/electron transport layer/cathode buffer layer/cathode/sealing adhesive/sealing member

[Structure of Organic Electroluminescent Illumination Panel]

Next, each structure member of the organic electroluminescent illumination panel according to the present invention is described.

(1) Injection Layer: Hole Injection Layer, Electron Injection Layer

In the organic electroluminescent illumination panel according to the present invention, the injection layer can be provided as necessary. As the injection layer, the electron injection layer (also called cathode buffer layer) and the hole injection layer are given, and the injection layer may be present between the anode and the light-emitting layer or the hole transport layer and between the cathode and the light-emitting layer or the electron transport layer.

In the present invention, the injection layer refers to the layer provided between the electrode and the organic function layer for reducing the drive voltage or improving the emission luminance. The details are disclosed in “2-2. Electrode material” (pp. 123-166) of “Organic EL element and its industrialization frontier (published on Nov. 30, 1998 by NTS)”, and the hole injection layer and the electron injection layer are given.

The details of the hole injection layer are disclosed in, for example, JP 9-45479 A, JP 9-260062 A, JP 8-288069 A, etc. and the hole injection materials applicable to the hole injection layer include polymer including a triazole derivative, an oxadiazole derivative, an imidazole derivative, a pyrazoline derivative and a pyrazolone derivative, a phenylene diamine derivative, an aryl amine derivative, an amino-substituted chalcone derivative, an oxazole derivative, a styryl anthracene derivative, a fluorenone derivative, a hydrazone derivative, a stilbene derivative, a silazane derivative, or the like, an aniline copolymer, a polyarylalkane derivative, and a conductive polymer. The hole injection material is preferably a polythiophene derivative, a polyaniline derivative, or a polypyrrole derivative, and more preferably a polythiophene derivative.

In the organic electroluminescent illumination panel according to the present invention, the electron injection layer may or may not be provided. As the electron injection layer applicable in the present invention, for example, the details are disclosed in JP 6-325871 A, JP 9-17574 A, JP 10-74586 A, and the like, and specifically a metal buffer layer typified by strontium, aluminum, or the like, an alkali metal compound buffer layer typified by lithium fluoride, an alkaline earth metal compound buffer layer typified by magnesium fluoride, an oxide buffer layer typified by aluminum oxide, and the like are given. In the present invention, the buffer layer (injection layer) is desirably an extremely thin film, and potassium fluoride and sodium fluoride are preferable and the thickness may be in the range of 0.1 nm to 5 μm, preferably 0.1 nm to 100 nm, more preferably 0.5 to 10 nm, and the most preferably 0.5 to 4 nm.

(2) Hole Transport Layer

As the hole transport material of the hole transport layer according to the present invention, a compound similar to the compound applied as the hole injection layer can be used; in addition, a porphyrin compound, an aromatic tertiary amine compound, and a styryl amine compound are preferably used and particularly an aromatic tertiary amine compound is particularly preferably used.

In the present invention, the hole transport layer can be formed by coating and drying in a wet coating method (for example, a spin coating method, a casting method, and a printing method including an ink jet method). As another method of forming the hole transport layer, the hole transport material can be formed to be thin by a known method such as a vacuum evaporation method or a Langmuir-Blodgett method (LB method).

(3) Electron Transport Layer

The electron transport layer according to the present invention includes the material with the function of transporting electrons, and in a broad sense, the electron injection layer and the hole block layer are also included in the electron transport layer. The electron transport layer may be used alone or a plurality of electron transport layers may be used. For example, the combination of the hole block layer/electron transport layer can be employed.

If the electron transport layer is used alone or a plurality of electron transport layers is used, the electron transport material used in the electron transport layer adjacent to the light-emitting layer on the cathode side (the material also serving as the hole block material) may have the function of transmitting the electrons injected from the cathode to the light-emitting layer, and the material may be selected arbitrarily from the conventionally known compounds. For example, a metal complex such as a fluorene derivative, a carbazole derivative, an azacarbazole derivative, an oxadiazole derivative, a triazole derivative, a silole derivative, a pyridine derivative, a pyrimidine derivative, and an 8-quinolinole derivative are given.

(4) Light-Emitting Layer

The light-emitting layer included in the organic electroluminescent illumination panel according to the present invention is the layer emitting light by the recombination of electrons and holes injected from the electrodes or the electron transport layer and the hole transport layer, and the portion emitting light may be either in the light-emitting layer or at the interface between the light-emitting layer and the adjacent layer.

The light-emitting layer mainly contains dopant and a host compound. The material of the light-emitting layer in the present invention is preferably a low-molecular-weight organic compound. The low-molecular-weight compound is a compound with a molecular weight of 1500 or less.

Description is hereinafter made of the host compound and the dopant.

<4. 1> Host Compound

As the host compound contained in the light-emitting layer of the organic electroluminescent illumination panel according to the present invention, a compound with a phosphorescence quantum yield of less than 0.1 at room temperature (25° C.) is preferable. The phosphorescence quantum yield is more preferably less than 0.01. Moreover, the non-light-emitting organic material may contain the host compound.

By using a plurality of kinds of the known host compounds and light-emitting materials to be described below, it is possible to obtain different emission colors, and by mixing these, any emission color such as white color can be expressed.

Specific examples of the known host compound include the compounds disclosed in the following literatures: JP 2001-257076 A, JP 2002-308855 A, JP 2001-313179 A, JP 2002-319491 A, JP 2001-357977 A, JP 2002-334786 A, JP 2002-8860 A, JP 2002-334787 A, JP 2002-15871 A, JP 2002-334788 A, JP 2002-43056 A, JP 2002-334789 A, JP 2002-75645 A, JP 2002-338579 A, JP 2002-105445 A, JP 2002-343568 A, JP 2002-141173 A, JP 2002-352957 A, JP 2002-203683 A, JP 2002-363227 A, JP 2002-231453 A, JP 2003-3165 A, JP 2002-234888 A, JP 2003-27048 A, JP 2002-255934 A, JP 2002-260861 A, JP 2002-280183 A, JP 2002-299060 A, JP 2002-302516 A, JP 2002-305083 A, JP 2002-305084 A, JP 2002-308837 A, and the like.

<4. 2> Light-Emitting Material

As the light-emitting material according to the present invention, a fluorescent light-emitting material and a phosphorescent light-emitting material (also called phosphorescent dopant) can be used; the phosphorescent dopant is preferably used.

The phosphorescent light-emitting material may be selected from the known materials that can be used for the light-emitting layer of the organic electroluminescent illumination panel; preferably, the material is the complex-based compound containing metal belonging to Groups 8 to 10 in the periodic table, and more preferably, the material is an iridium compound, an osmium compound, a platinum compound (platinum complex-based compound), and a rare-earth metal complex. The most preferable material is the iridium compound.

(5) Anode

For the anode of the organic electroluminescent element, the metal, the alloy, the electrically conductive compound with a large work function (4 eV or more), or the mixture thereof is preferably used as the electrode material. Specific examples of the electrode material include metal such as Au, and transparent conductive materials such as CuI, indium tin oxide (ITO), SnO₂, and ZnO.

Moreover, the material that can manufacture an amorphous transparent conductive film such as IDIXO (In₂O₃—ZnO) may be used. The anode may be formed by forming a thin film of these electrode materials through a method of evaporation or sputtering and forming a desired shaped pattern by a photolithography method. If a high degree of pattern accuracy is not required (100 μm or more), the pattern may be formed through a mask with a desired shape when the electrode material is evaporated or sputtered.

Alternatively, when the applicable material such as an organic conductive compound is used, a wet deposition method such as a printing method or a coating method can be used. In the case of extracting the light from the anode, the transmissivity is preferably set higher than 10%. The sheet resistance of the anode is preferably several hundred Ω/square or less. The thickness is, though depending on the material, generally selected from the range of 10 to 1000 nm, preferably 10 to 200 nm.

(6) Cathode

On the other hand, for the cathode, the metal (referred to as electron injection metal), the alloy, the electrically conductive compound with a small work function (4 eV or less), or the mixture thereof is preferably used as the electrode material.

Specific examples of the electrode material include sodium, sodium-potassium alloy, magnesium, lithium, magnesium/copper mixture, magnesium/silver mixture, magnesium/aluminum mixture, magnesium/indium mixture, aluminum/aluminum oxide (Al₂O₃) mixture, indium, lithium/aluminum mixture, and rare-earth metal.

Among these, from the viewpoint of the electron injection property and the resistance against oxidation, etc., the mixture of the metal with the electron injection property and the second metal that is stable and has the larger work function, such as magnesium/silver mixture, magnesium/aluminum mixture, magnesium/indium mixture, aluminum/aluminum oxide (Al₂O₃) mixture, lithium/aluminum mixture, or aluminum is preferable.

The cathode can be formed by forming a thin film of the electrode material by a method of evaporation, sputtering, or the like. The sheet resistance of the cathode is preferably several hundred Ω/square or less. The thickness is, though depending on the material, generally selected from the range of 10 nm to 5 μm, preferably 50 to 200 nm.

For transmitting the emitted light, either one of or both the anode and the cathode of the organic electroluminescent element may be transparent or half-transparent; it is preferable that the light is not leaked to the rear side of the organic electroluminescent illumination panel.

(7) Support Substrate

There is no particular limitation on the support substrate (hereinafter also referred to as base, substrate, base material, supporter, or the like) that can be used for the organic electroluminescent element of the present invention and any kind of glass, plastic, or the like can be used. However, the support substrate is preferably transparent because when the support substrate is formed of a transparent material, it is easier to extract light from the support substrate side.

As the transparent substrate preferably used, glass, quartz, and a transparent resin film is given. The particularly preferable support substrate is a resin film that can make the organic electroluminescent element flexible.

Examples of the resin film include polyesters such as polyethylene terephthalate (PET) and polyethylene naphthalate (PEN), cellulose esters such as polyethylene, polypropylene, cellophane, cellulose diacetate, cellulose triacetate (TAC), cellulose acetate butylate, cellulose acetate propionate (CAP), cellulose acetate phthalate, and cellulose nitrate, and derivatives thereof, polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluorine resin, nylon, polymethyl methacrylate, acrylic, or polyarylates, and cycloolefine-based resin such as ARTON (product name, manufactured by JSR) or APEL (product name, manufactured by MITSUI CHEMICALS).

### INDUSTRIAL APPLICABILITY

The portable information appliance according to the present invention is the portable information appliance having the thin organic electroluminescent illumination panel capable of color adjustment and uniform light emission, and is suitably applicable to tablet type information terminals, smart phones, digital cameras, and the like.

### REFERENCE SIGNS LIST

1 Organic electroluminescent illumination panel
2 Front transmissive member
3 Transparent adhesive
4, 4a, 4b Exterior member
5 Double-sided tape
6 Diffusion plate
7 Circuit board
8 Flexible wire
9 Organic electroluminescent illumination panel connector
10 Circuit board side connector
21 Display screen
22 Photographing lens
23 Light-emitting portion (illumination of logo mark or illumination that notifies incoming call)
24 Light-emitting portion (auxiliary light)
40, 50 Organic electroluminescent illumination panel
41, 51 Support substrate
42, 52 Transparent electrode (anode)
43, 45, 53, 55 Organic function layer
44 Organic light-emitting layer
54a Blue-light-emitting layer
54b Blue-light-emitting layer
54c Blue-light-emitting layer
46, 56 Electrode
47, 57 Sealing member
C Organic function layer unit

1. A portable information appliance comprising an organic electroluminescent illumination panel, wherein the organic electroluminescent illumination panel is integrated with a front transmissive member and fitted into an exterior member of the portable information appliance.

2. The portable information appliance according to claim 1, wherein the organic electroluminescent illumination panel is capable of color adjustment.

3. The portable information appliance according to claim 1, wherein the organic electroluminescent illumination panel is used as auxiliary light in photographing.

4. The portable information appliance according to claim 1, wherein the organic electroluminescent illumination panel is used to illuminate a logo mark.

5. The portable information appliance according to claim 1, wherein the organic electroluminescent illumination panel is used for illumination that notifies an incoming call.

6. The portable information appliance according to claim 1, wherein the portable information appliance is any of a tablet type terminal, a smart phone, and a digital camera.

7. The portable information appliance according to claim 2, wherein the organic electroluminescent illumination panel is used as auxiliary light in photographing.

8. The portable information appliance according to claim 2, wherein the organic electroluminescent illumination panel is used to illuminate a logo mark.

9. The portable information appliance according to claim 2, wherein the organic electroluminescent illumination panel is used for illumination that notifies an incoming call.

10. The portable information appliance according to claim 2, wherein the portable information appliance is any of a tablet type terminal, a smart phone, and a digital camera.

11. The portable information appliance according to claim 3, wherein the organic electroluminescent illumination panel is used to illuminate a logo mark.

12. The portable information appliance according to claim 3, wherein the organic electroluminescent illumination panel is used for illumination that notifies an incoming call.

13. The portable information appliance according to claim 3, wherein the portable information appliance is any of a tablet type terminal, a smart phone, and a digital camera.

14. The portable information appliance according to claim 4, wherein the organic electroluminescent illumination panel is used for illumination that notifies an incoming call.

15. The portable information appliance according to claim 4, wherein the portable information appliance is any of a tablet type terminal, a smart phone, and a digital camera.

16. The portable information appliance according to claim 5, wherein the portable information appliance is any of a tablet type terminal, a smart phone, and a digital camera.
